(19) United States
(12) Patent Application Publication
(10) Pub. No.: US 2020/0411580 A1
(43) Pub. Date: Dec. 31, 2020

(54) METHOD OF MANUFACTURING CISCSP WITHOUT DAM

(71) Applicant: SEMICONDUCTOR COMPONENTS INDUSTRIES, LLC, Phoenix, AZ (US)

(72) Inventor: Shou-Chian HSU, Zhubei City (TW)

(73) Assignee: SEMICONDUCTOR COMPONENTS INDUSTRIES, LLC, Phoenix, AZ (US)

(21) Appl. No.: 16/451,418

(22) Filed: Jun. 25, 2019

(51) Int. Cl. H01L 27/146; H01L 23/00; H01L 23/48; H01L 21/56

(52) U.S. Cl. CPC H01L 27/14636; H01L 24/08; H01L 24/32; H01L 23/481; H01L 2924/15311; H01L 27/14687; H01L 27/14618; H01L 21/565; H01L 2224/02372; H01L 27/14685

(57) ABSTRACT

Implementations of semiconductor packages may include: a die having a first side and a second side and at least two through silicon vias (TSVs) extending from a first side of the die to the second side of the die. Semiconductor packages may also include a glass lid coupled to a second side of the die through adhesive. The adhesive may be positioned over the at least two TSVs. Semiconductor packages may also include a molding compound around a perimeter of the die, extending from the first side of the die to at least the glass lid.

### BACKGROUND

### 1. Technical Field

Aspects of this document relate generally to semiconductor packages, such as image sensor devices. More specific implementations involve image sensor packages having glass lids.

### 2. Background

Image sensors are designed to generate electrical signals in response to light radiation received. A wide variety of image sensor devices have been devised including complementary metal oxide semiconductor (CMOS) and charge coupled devices (CCDs).

### SUMMARY

Implementations of semiconductor packages may include: a die having a first side and a second side and at least two through silicon vias (TSVs) extending from a first side of the die to the second side of the die. Semiconductor packages may also include a glass lid coupled to a second side of the die through adhesive. The adhesive may be positioned over the at least two TSVs. Semiconductor packages may also include a molding compound around a perimeter of the die, extending from the first side of the die to at least the glass lid.

Implementations of semiconductor packages may include one, all, or any of the following:

Semiconductor packages may further include a redistribution layer (RDL) on a first side of the die.

Semiconductor packages may further include a ball grid array coupled to the RDL.

Semiconductor packages may further include a die pad between the adhesive and the TSV.

The glass lid may include a cavity forming a gap between the active area of the die and the glass lid.

Implementations of semiconductor packages may be formed using implementations of methods for forming semiconductor package, and the methods may include: providing a glass cover with a plurality of cavities formed on a first side of the cover. The method may also include applying adhesive to the glass cover on a first side and a second side of each of the plurality of cavities and coupling a plurality of die to each of the plurality of cavities through the adhesive. The method may include applying a molding compound over the plurality of die and to the first side of the glass cover. After applying the molding compound, the method may include forming at least two through silicon vias (TSVs) through each of the plurality of die. The TSVs may be positioned around an active area of the die. The method may include forming a redistribution layer (RDL) on the first side of each of the plurality of die. The RDL may extend over the TSVs. The method may include singulating each of the plurality of die to form a plurality of semiconductor packages.

Implementations of methods of forming semiconductor packages may include one, all, or any of the following:

The method may further include applying a ball grid array to the RDL over each of the plurality of die.

The method may further include forming at least two TSVs through each of the plurality of die and forming a redistribution layer on the first side of each of the plurality of die may occur before applying the molding compound.

The method may further include applying the adhesive may include the applying the adhesive over a die pad.

The method may further include thinning the molding compound and a first side of each of the plurality of die.

The die may be an image sensor.

The method may further include filling at least a portion of the TSVs with the adhesive.

Implementations of semiconductor packages may be formed using implementations of methods for forming semiconductor package, the methods may include: providing a glass cover with a plurality of cavities on a first side of the cover. The method may include applying an adhesive to the glass cover between each of the plurality of cavities. The method may include coupling a semiconductor wafer to the glass cover over the plurality of cavities. Each of a plurality of die correspond with each of the plurality of cavities. The method may include thinning a first side of the semiconductor wafer. The method may include forming at least two through silicon vias (TSVs) through each of the plurality of die. The TSVs may be positioned around an active area of the die. The method may include forming a redistribution layer (RDL) on the first side of each of the plurality of die. The RDL may extend over the TSVs. The method may include performing a first cut between each of the plurality of die. The method may also include applying a molding compound over the plurality of die. The molding compound may extend to the first side of the glass cover. The method may also include performing a second cut between each of the plurality of die.

Implementations of methods of forming semiconductor packages may include one, all, or any of the following:

Performing the first cut may extend only through the semiconductor wafer.

Performing the first cut may extend through the semiconductor wafer and the glass cover between the plurality of die and plurality of cavities, respectively.

The method may further include applying a ball grid array to a first side of each of the plurality of die.

The method may further include coupling a second side of the glass cover to a carrier wafer.

The method may further include removing each of the plurality of semiconductor wafers from the carrier wafer after performing the second cut.

The method may also include where performing the first cut may extend only through the semiconductor wafer.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a semiconductor package;

FIG. 2 is a cross sectional view of an implementation of a glass cover having grooves therein;

FIG. 3 is a cross sectional view of an implementation of a glass cover having adhesive applied thereon;

FIG. 4 is a cross sectional view of an implementation of a semiconductor die coupled to an implementation of a glass cover;

FIG. 5 is a cross sectional view of an implementation of a molding compound applied over implementations of semiconductor dies coupled to a glass cover;

FIG. 6 is a cross sectional view of an implementation of thinned molding compound;

FIG. 7 is a cross sectional view of an implementation of through silicon vias in implementations of semiconductor die;

FIG. 8 is cross sectional view of an implementation of a redistribution layer and ball grid array coupled to implementations of semiconductor die;

FIG. 9 is a cross sectional view of an implementation of singulating implementations of semiconductor packages;

FIG. 10 is a cross sectional view of an implementation of a semiconductor package;

FIG. 11 is a cross sectional view of an implementation of a glass cover having grooves therein;

FIG. 12 is a cross sectional view of an implementation of a glass cover having adhesive applied thereon;

FIG. 13 is a cross sectional view of an implementation of a semiconductor die coupled to an implementation of a glass cover;

FIG. 14 is a cross sectional view of an implementation of molding compound applied over and between implementations of a semiconductor die and a glass cover;

FIG. 15 is a cross sectional view of an implementation of singulating implementations of semiconductor packages;

FIG. 16 is a cross sectional view of an implementation of a semiconductor package;

FIG. 17 is a cross sectional view of an implementation of a glass cover having cavities therein;

FIG. 18 is a cross sectional view of an implementation of a glass cover having adhesive applied between the cavities of the glass lid;

FIG. 19 is a cross sectional view of an implementation of a semiconductor wafer coupled to an implementation of a glass cover;

FIG. 20 is a cross sectional view of an implementation of a semiconductor wafer after thinning;

FIG. 21 is a cross sectional view of an implementation of a semiconductor wafer after formation of implementations of through silicon vias (TSVs);

FIG. 22 is a cross sectional view of an implementation of semiconductor wafer coupled to a glass lid after formation of a redistribution layer and coupling of a ball grid array;

FIG. 23 is cross sectional view of an implementation of an array of semiconductor packages after a first cut through the semiconductor wafer;

FIG. 24 is cross sectional view of an implementation of an array of semiconductor packages applying molding compound;

FIG. 25 is a cross sectional view of an implementation of an array of semiconductor packages after a second cut through the implementations of glass lids;

FIG. 26 is a cross sectional view of an implementation of a semiconductor package;

FIG. 27 is a cross sectional view of an implementation of a glass cover coupled to a carrier wafer;

FIG. 28 is a cross sectional view of an implementation of a glass cover coupled to a carrier wafer having adhesive applied between the cavities of the glass lid;

FIG. 29 is a cross sectional view of an implementation of a semiconductor wafer coupled to an implementation of a glass cover;

FIG. 30 is a cross sectional view of an implementation of a semiconductor wafer after thinning;

FIG. 31 is a cross sectional view of an implementation of a semiconductor wafer after formation of implementations of through silicon vias (TSVs);

FIG. 32 is a cross sectional view of an implementation of a semiconductor wafer coupled to a glass lid after formation of a redistribution layer and coupling of a ball grid array;

FIG. 33 is cross sectional view of an implementation of an array of semiconductor packages after a first cut through the semiconductor wafer and the glass lid array;

FIG. 34 is cross sectional view of an implementation of an array of semiconductor packages after applying molding compound;

FIG. 35 is a cross sectional view of an implementation of an array of semiconductor packages after a second cut through the molding compound;

FIG. 36 is a cross sectional view of an implementation of a semiconductor package; and

FIG. 37 is a top perspective view a glass cover with a plurality of cavities on a first side of the cover.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

Referring to FIG. 1, an implementation of a semiconductor package 2 is illustrated. The semiconductor package 2 includes a glass lid 4 coupled to a semiconductor die 6. In various implementations, the lid of the package may be formed of other optically transparent or translucent material other than glass such as, by non-limiting example, polycarbonate, acrylic, plastics, or other materials that allow some or all of a desired wavelength of light to pass through the material. The glass lid 4 includes a cavity 5 or groove on a first side of the lid. The cavity 5 forms a gap 7 between the active area of the die 6 and the lid 4. The glass lid 4 is coupled to the semiconductor die 6 through an adhesive 8. In various implementations, the adhesive may include, by non-limiting example, epoxy, resin, polymers, glue, and other adhesive materials used in coupling components of semiconductor devices. In some implementations, the adhesive may include silver or other metal fillers to create electrical conductivity for the adhesive. In this particular implementation, the adhesive 8 is positioned between the glass lid 4 and a die pad 10. The die pad 10 is within a through silicon via (TSV) 11 located on either side of the active area of the die. In various implementations, the die may be an image sensor die and the package may include a complementary metal oxide semiconductor (CMOS) image sensor (CIS) chip scale package (CISCSP).

Still referring to FIG. 1, the semiconductor die is illustrated being encapsulated in a molding compound 12. In various implementations, the entire die is encapsulated in the molding compound. The semiconductor package also include a redistribution layer (RDL) 14 coupled to a first side of the semiconductor die 6. A ball grid array 16 may be coupled to the RDL 14 on the first side of the semiconductor die 6. In some implementations, other interconnects for surface mount devices may be used. The ball grid array may include solder, copper, lead, silver, aluminum, or other conductive materials.

The structure of this semiconductor package may have advantages over various packages including those with dams that separate the lid from the semiconductor die. A smaller non-active area of the die is needed when dams are not used. The non-use of dams may allow for a smaller overall size for the semiconductor package. Another advantage of implementations of semiconductor packages as described herein may include higher reliability and die protection due to the die being completely encapsulated by a molding compound. Various methods of manufacturing semiconductor packages as described herein may be used including wafer level processes and panel level processes. Panel level processes may have cost and productivity advantages. Panel level processing may allow for parallel processing of more units of semiconductor packages in a given period compared with wafer level processes.

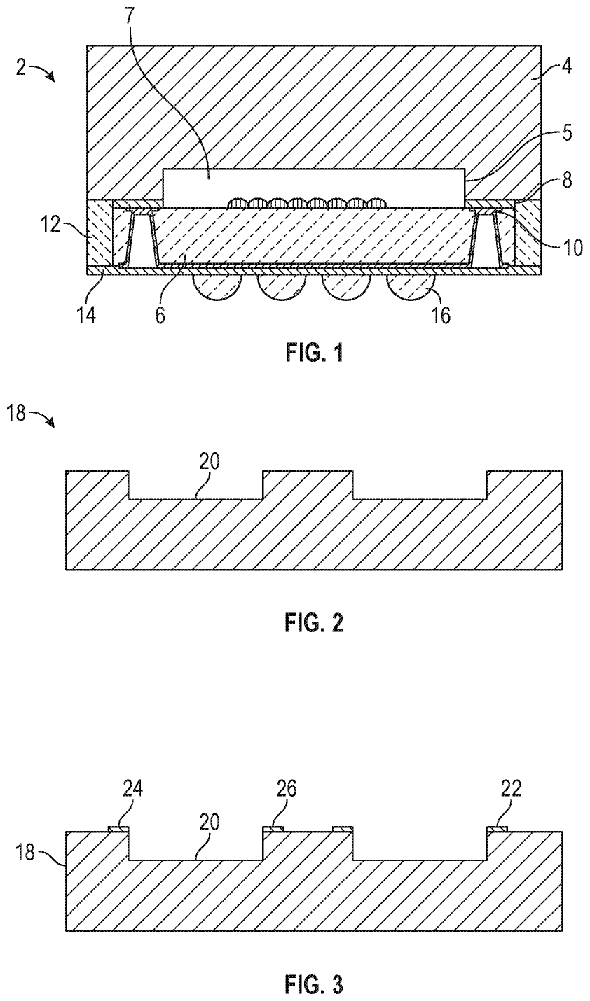

Referring to FIG. 2, a cross sectional view of a portion of a panel of glass covers 18 is illustrated. The glass cover includes a plurality of cavities 20 formed on a first side of the cover. A method for forming a semiconductor package may include providing a cover as illustrated. The method may also include applying adhesive to the glass cover on the first side of the cover. The adhesive may be applied to a first side and a second side of each of the plurality of a cavities. Referring to FIG. 3, an implementation of a glass cover 18 having adhesive 22 applied on a first side 24 and a second side 26 of the cavities is illustrated (a first perimeter of a first cavity and a second perimeter of a second cavity).

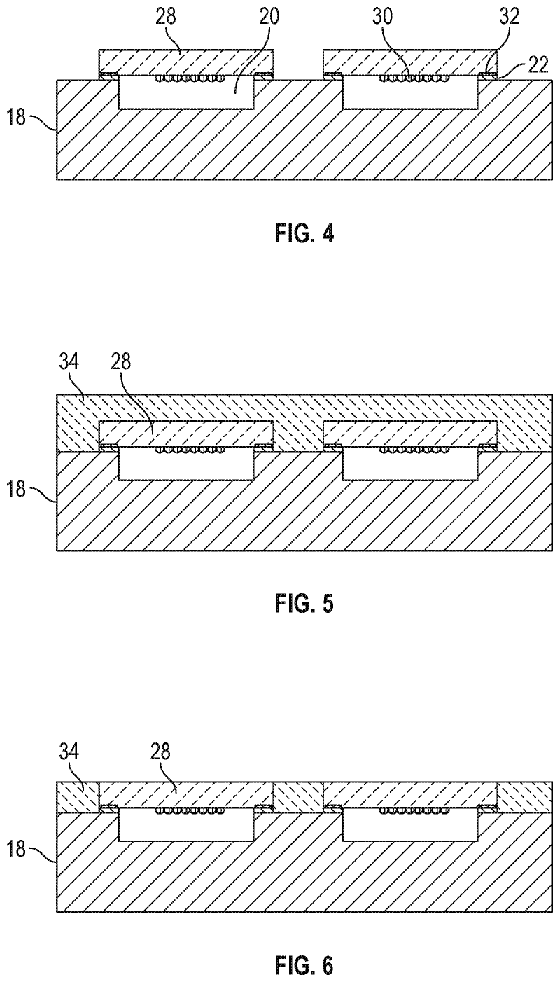

The method may further include coupling a plurality of die to each of the plurality of cavities through the adhesive. Referring to FIG. 4, two die 28 coupled over two cavities 20 within the glass panel 18 is illustrated. The active area 30 of the die 28 is positioned within the cavity. The adhesive 22 is illustrated coupled to die pads 32 on either side of the active area 30 of the die 28. The method may further include applying a molding compound over the plurality of die. The molding compound may also extend to the first side of the glass cover. FIG. 5 illustrates the lid 18 and die 28 after molding compound 34 has been applied. In various implementations, the molding compound may include, by non-limiting example, epoxies, resins, polymers, and other materials used to seal the die to the glass lid.

The method may also include thinning/planarizing the molding compound. The molding compound may be thinned through, by non-limiting example, grinding, polishing, or other methods for reducing the thickness of molding compound after setting. Referring to FIG. 6, the lid 18 and die 28 coupled thereto are illustrated after thinning of the molding compound 34. In various implementations, thinning the molding compound may also include thinning a portion of the die. In other implementations, thinning the molding compound may include leaving a thin layer of molding compound over the surface of the die.

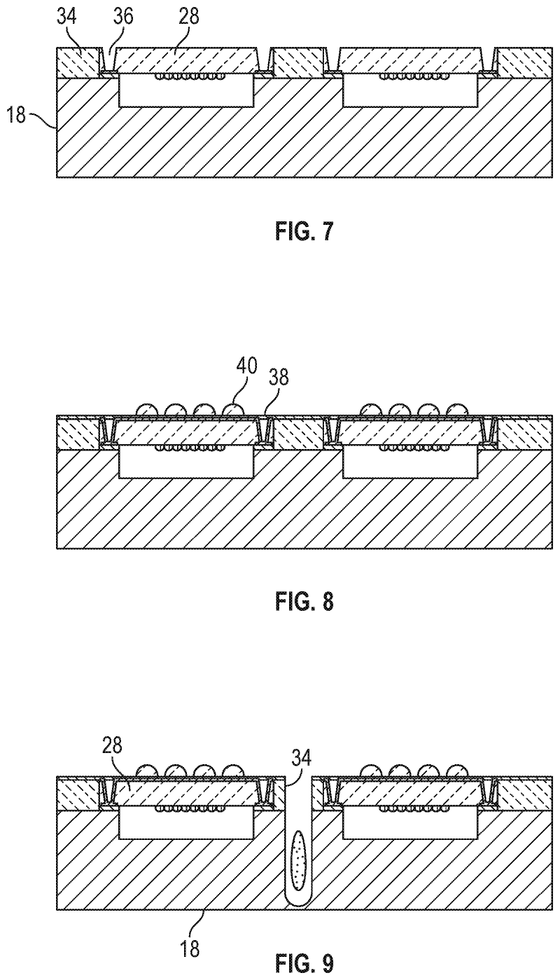

The method may also include forming through silicon vias (TSVs) in the die. The TSVs may be formed on either side of the active area of the die. The TSVs may extend from the first side of the die to the second side of the die meeting with the adhesive on the lid. In some implementations, the TSVs may extend to a die pad in the die. The TSV may be formed through drilling, etching, or other methods of passing through a semiconductor die. Referring to FIG. 7, the die 28 coupled to the glass lid 18 are illustrated after forming of the TSVs 36.

The method also includes forming a redistribution layer (RDL) 38 on the first side of each of the plurality of die. The RDL may extend over the TSVs. After the RDL has been forming on the die a surface mount interconnect may be coupled to the RDL. In various implementations, the surface mount interconnect may be a ball grid array. Referring to FIG. 8, the die is illustrated after the RDL 38 has been formed and the ball grid array (BGA) 40 has been coupled to the first side of the die. As illustrated, the BGA extends over the molding compound.

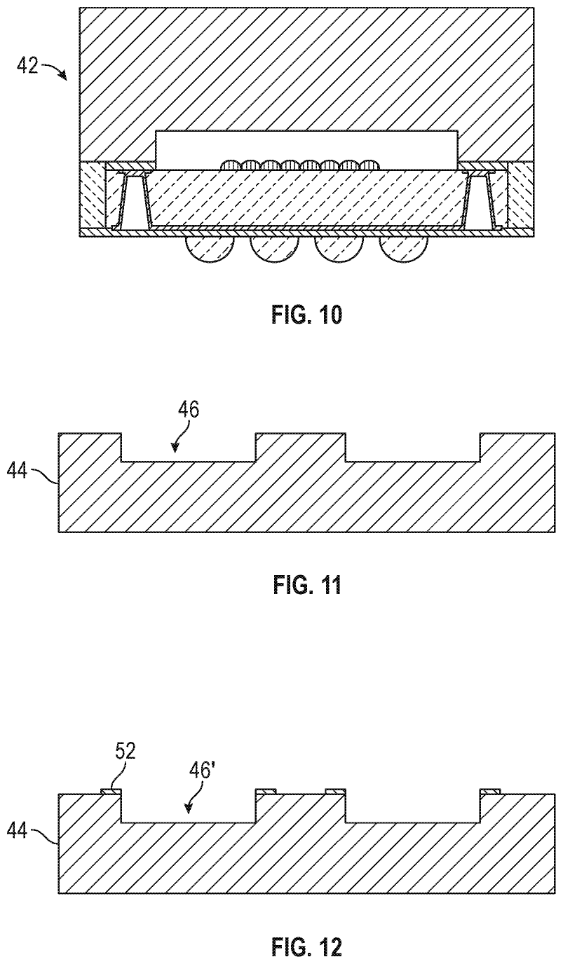

The method further includes singulating each of the plurality of die to form a plurality of semiconductor packages. The plurality of die may be singulated through, by non-limiting example, cutting, grinding, drilling, or other suitable method for singulating through semiconductor material and glass. Referring to FIG. 9, an implementation of singulating through both the molding material 34 and the lid 18 is illustrated. Referring to FIG. 10, an implementation of a semiconductor package 42 after singulation is illustrated.

Referring to FIG. 11, a cross sectional view of an implementation of a glass cover 44 is illustrated. In FIG. 11, a close up view of the glass cover 44 is illustrated having only two cavities 46 in the lid illustrated. Referring to FIG. 38, a full panel of a glass lid 48 having a plurality of cavities 50 is illustrated. In various implementations of the methods described herein, a large panel may be used or a smaller panel including less cavities may be used. An implementation of a method of forming semiconductors may include providing a glass cover as illustrated in FIG. 11. As illustrated the cavities 46 are formed on the first side of the cover 44. The method may also include applying adhesive to the first side of the glass cover. The adhesive may be applied on both a first side and a second side of each of the cavities. Referring to FIG. 12, the cover is illustrated after applying adhesive on both sides of each of the plurality of cavities (around the perimeters of both of the cavities).

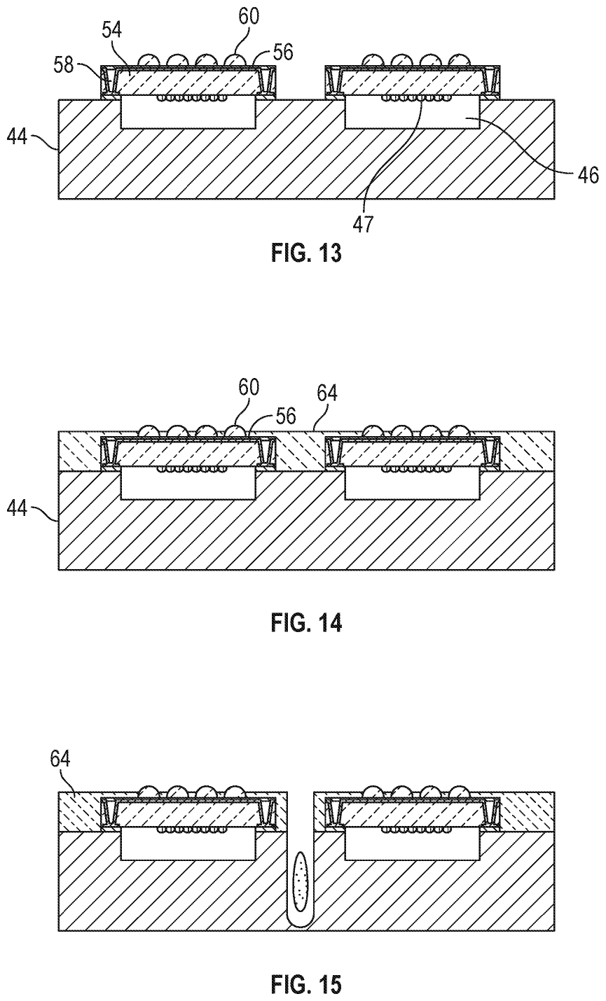

The method may also include coupling a plurality of semiconductor die 54 over each of the plurality of cavities 46 in the glass lid 44. As illustrated in FIG. 13, in this particular method the semiconductor die 54 that are coupled over the cavities 46 include a redistribution layer (RDL) 56 formed on a first side of the die 54 over two through silicon vias 58 (TSVs). A ball grid array 60 is illustrated coupled to the first side of the semiconductor die 54. The plurality of die 54 are coupled to the glass lid with the active area 47 of the die positioned within the cavity 46 of the lid 44.

The method also includes applying a molding compound over the plurality of die. The molding compound may fully encapsulate each of the plurality of die. The molding compound may also provide a tight seal with the surface of the glass lid. As illustrated in FIG. 14, the molding compound 64 encapsulates the die including the RDL 56 and surrounds a portion the BGA 60. After encapsulation in this particular method, the plurality of die are singulated to form a plurality of individual semiconductor packages. Referring to FIG. 15, a schematic illustrates singulation of the packages. In various implementations, singulation may include sawing or etching.

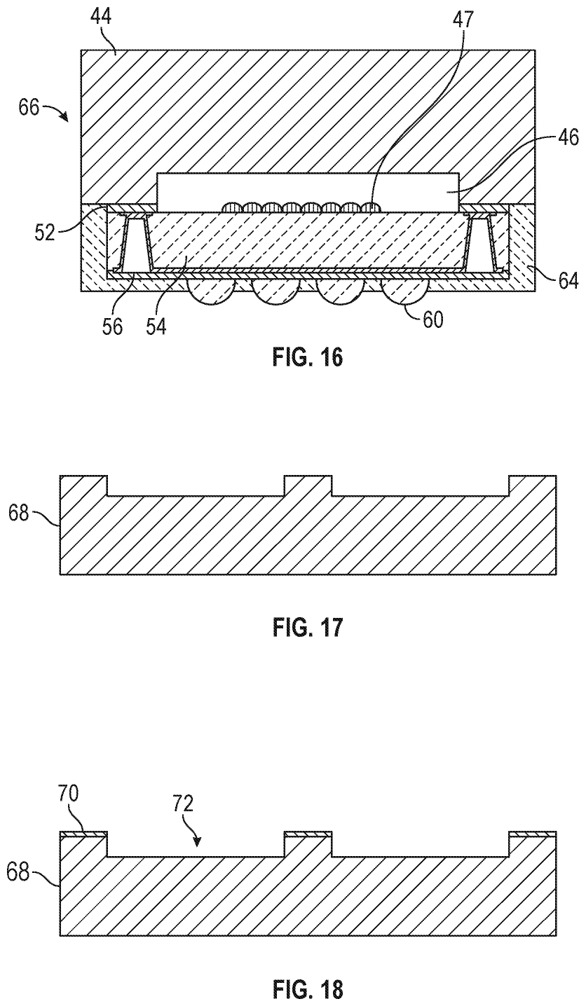

In FIG. 16, an implementation of an individual semiconductor package is illustrated after singulation. The package 66 includes an image sensor die 54 coupled to a glass lid 44 through adhesive 52. The adhesive 52 is positioned on either side of the active area 47 of the die 54. The active area 47 is positioned within in the cavity 46 of the lid 44. This package requires a smaller area of non-active area of the die than packages using dams to provide a space between the die and the lid. Reliability of the package 66 may be improved due to the molding compound 64 fully encapsulating the die 54 including the RDL 56 and the BGA 60.

Another method of forming a plurality of semiconductor packages may include providing a wafer size panel of a glass lid having a plurality of cavities on a first side of the cover. A cross sectional view of a portion of a wafer size panel is illustrated in FIG. 38. Referring to FIG. 17, a side view of a partial panel of a glass lid 68 is illustrated. A partial panel is illustrated to reduce space and show detail. The method may also include applying adhesive 70 to the glass cover 68 between each of the plurality of cavities 72 (around a perimeters of each of the plurality of cavities 72). As illustrated in FIG. 18, the adhesive 70 extends from one cavity 72 to the next. In this particular implementation, more of the glass is covered with adhesive than illustrated in the other methods.

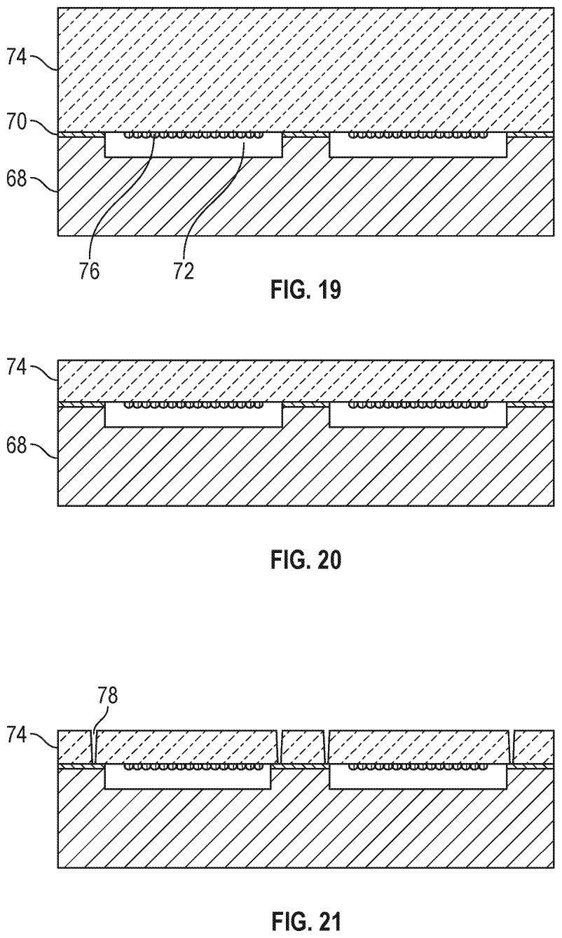

The method may also include coupling a semiconductor wafer to a first side of the glass lid panel. The semiconductor wafer 74 is coupled to the glass lid 68 through the adhesive 70 as illustrated in FIG. 19. Each of the plurality of active areas 76 of the semiconductor wafer 74 is coupled over one of the plurality of cavities 72 on the first side of the glass lid 68. The method may further include thinning the semiconductor wafer to a desired thickness. The wafer may be thinned through grinding, etching, or other methods of thinning semiconductor wafers. Referring to FIG. 20, the semiconductor wafer 74 coupled to the glass lid 68 is illustrated after the wafer 74 has been thinned to a predetermined thickness.

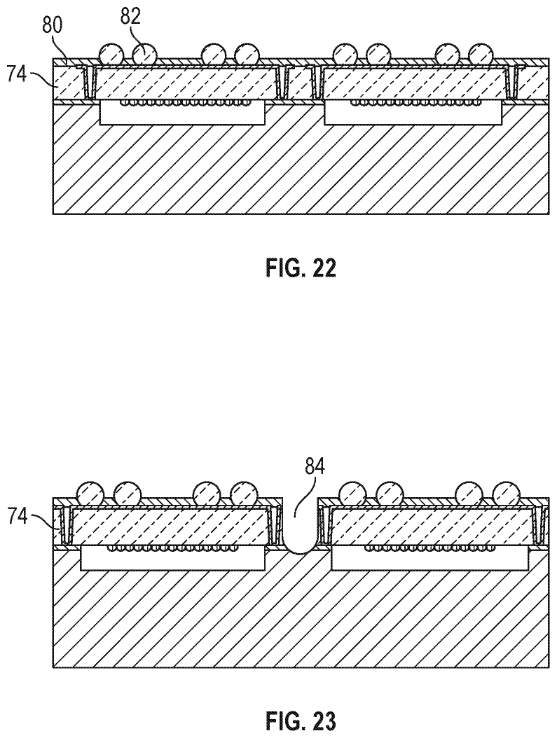

The method may further include forming through silicon vias (TSVs) in the semiconductor wafer. Two or more TSVs may be formed around each of the active areas of the plurality of die within the semiconductor wafer. The TSVs may be formed through the wafer through, by non-limiting example, drilling, etching, or other methods for forming TSVs in a semiconductor wafer. The TSVs may extend to the adhesive positioned on the glass lid. In other implementations, the TSVs may extend to a die pad within the semiconductor wafer. Referring to FIG. 22, an implementation of the wafer 74 after formation of the TSVs 78 is illustrated.

The method may also include forming a redistribution layer on a second side of each of the plurality of die within the semiconductor wafer. In various implementations, the RDL may be formed around the inner walls of the TSVs. In other implementations, the RDL may be formed over the opening of the TSV on the first side of the die. A ball grid array may be coupled to the redistribution layer. The BGA may also be coupled directly to the first side of the semiconductor die. Referring to FIG. 22, an implementation of the RDL 80 and the BGA 82 on the second side of each of the plurality of die 74 is illustrated.

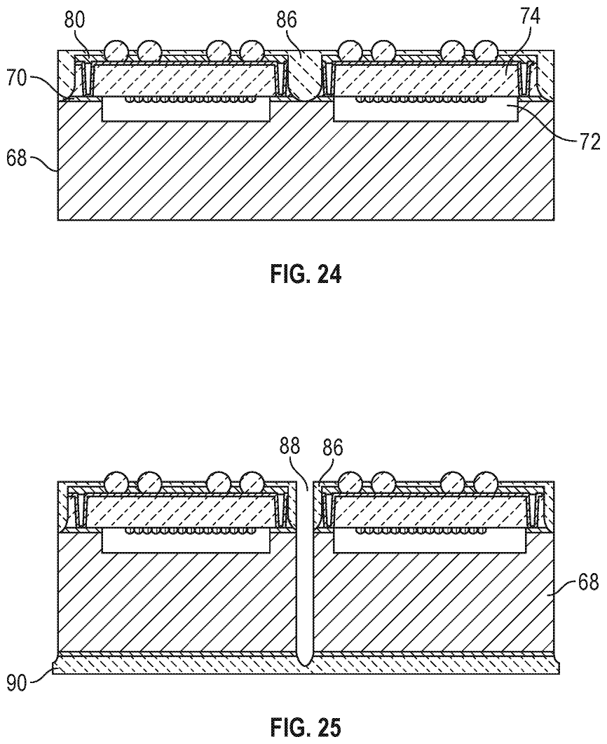

The method may further include performing a first cut between each of the plurality of die. In this particular implementation, the first cuts extends only through the semiconductor wafer material and the adhesive. Referring to FIG. 23, an implementation of the wafer 74 after the first cut 84 is illustrated. After the first cut, the method includes applying a molding compound around each of the plurality of die. As illustrated in FIG. 24, the molding compound 86 may extend through the cut in the adhesive 70 and couple with the first side of the glass lid 68 between the plurality of cavities 72. The molding compound 86 fully encapsulates each of the plurality of die 74 including the RDL 80 on each die.

The method may further include making a second cut. The second cut 88 may extend through the molding compound 86 and through the glass lid 68 to fully encapsulate each of the plurality of semiconductor packages. As illustrated in FIG. 25, the glass lid 68 may be coupled to a carrier wafer 90 to provide stability during the cutting process. After singulation, each of the plurality of semiconductor devices may be removed through a pick and place method. In other implementations, the panel may be coupled to a wafer/support chuck during the cutting process. In still other implementations, the panel may not be coupled to any additional structure prior to cutting.

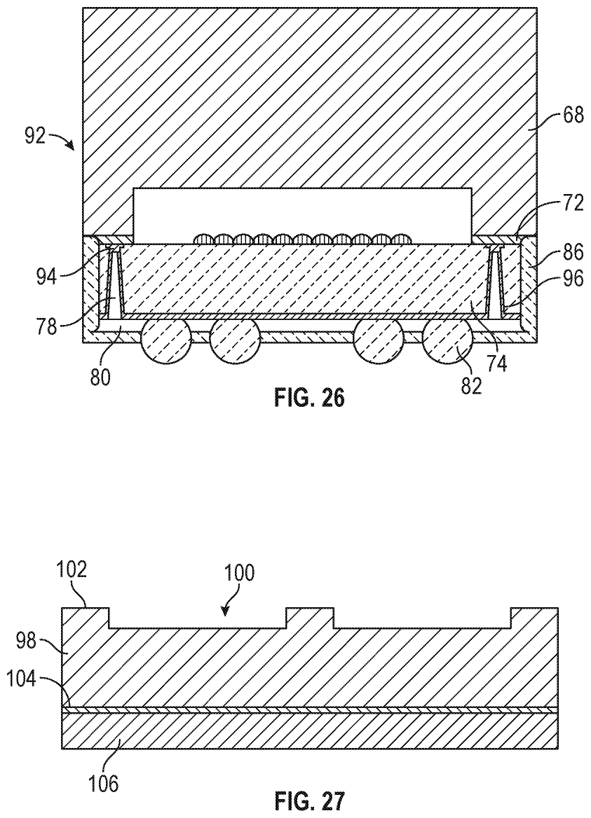

Referring to FIG. 26, a semiconductor package is illustrated after singulation. The package 92 includes the glass lid 68 coupled to the image sensor die 74 through the adhesive 72. In this view, the molding compound 86 encapsulating the die 74 and coupling with the glass lid 68 at an edge of the adhesive 72 is visible. The TSVs are illustrated extending to a die pad 94. The die pad 94 is covered with the adhesive 72 and electrically coupled with the RDL 80 and BGA 82 through metal plating 96 lining the walls of the TSVs 78.

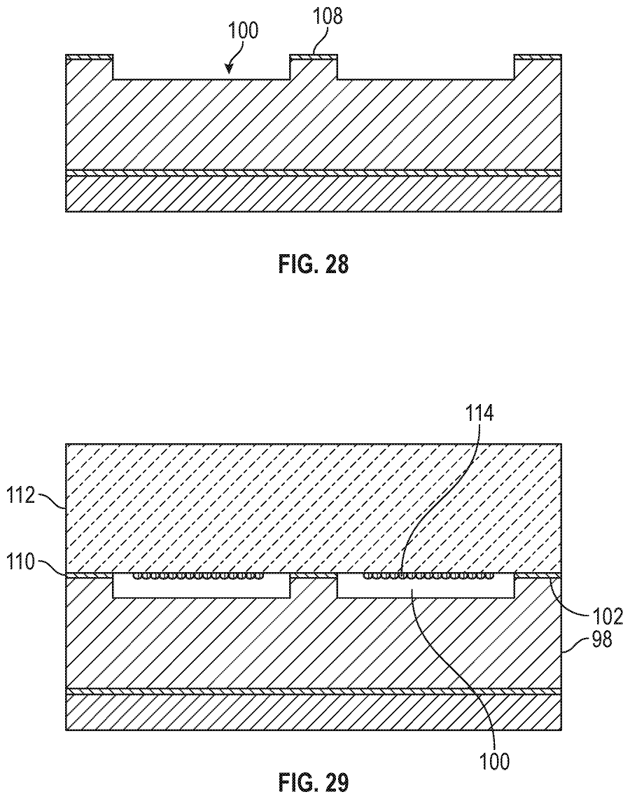

Another implementation of a method of forming semiconductor packages may also include wafer level manufacturing processes. The method may include providing a panel of glass lids 98 having a plurality of cavities 100 formed on a first side 102 of the glass panel 98. A second side 104 of the panel of lids 98 may be coupled to a carrier wafer 106 as illustrated in FIG. 27. The method may also include applying an adhesive between each of the plurality of cavities (around a perimeter of each of the plurality of cavities). The adhesive 108 extends from one cavity 100 to another cavity as illustrated in FIG. 28.

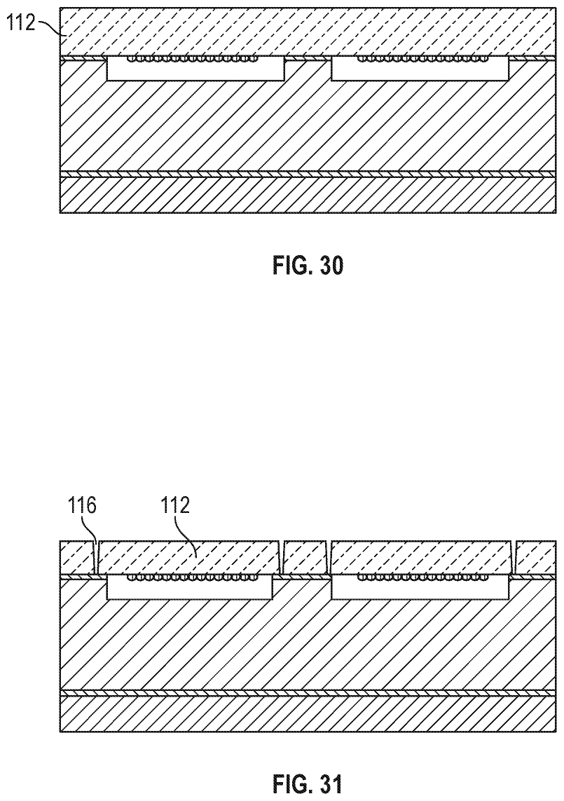

The method may further include coupling a second side 110 of a semiconductor wafer 112 to a first side 102 of the glass panel 98. The active areas 114 of each of the plurality of die may be positioned within a cavity 100 of the glass panel 98. An implementation of a semiconductor wafer 112 coupled to a glass lid 98 through adhesive 110 is illustrated in FIG. 29. The method may also include thinning the semiconductor wafer to a predetermined thickness. The wafer may be thinned through, by non-limiting example, grinding, etching, sawing, and other methods of thinning a semiconductor wafer. Referring to FIG. 30, an implementation of the wafer 112 after thinning is illustrated.

The method may also include forming through silicon vias (TSVs) in the wafer. The TSVs may be formed on either side of the active areas of each of the plurality of die. The TSVs may extend from a first side of the die to a second side of the die. In various implementations, the TSVs 116 may extend to the adhesive coupled on the glass lid. In other implementations, the TSVs may extend to a die pad positioned on both sides of the active area of each of the plurality of die. Referring to FIG. 31, an implementation of the semiconductor wafer 112 after formation of the TSVs 116 is illustrated.

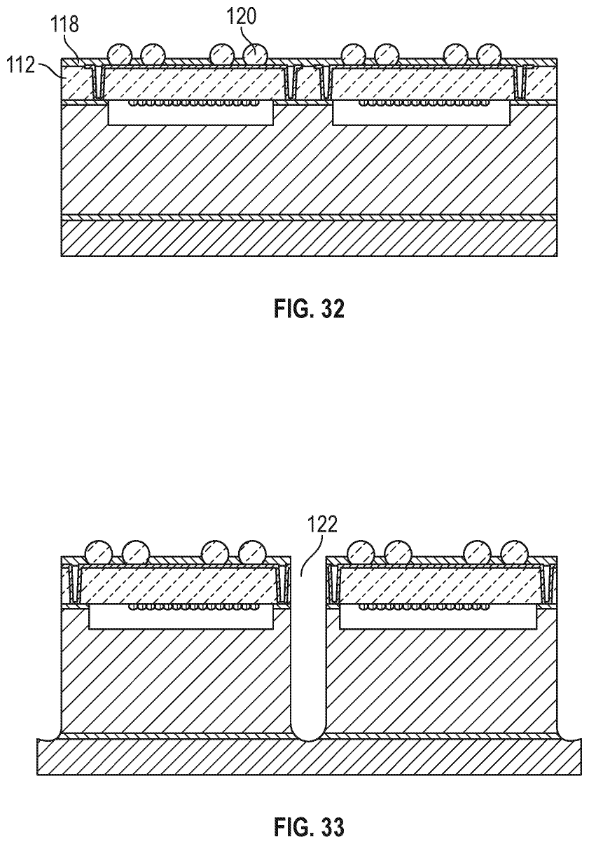

The method may also include forming a redistribution layer (RDL) on a first side of each of the plurality of die. A ball grid array (BGA) may be coupled to the first side of each of the die. In various implementations, the BGA may include, by non-limiting example, solder, copper, and other conductive materials. Referring to FIG. 32, an implementation of the wafer 112 after formation of the RDL 118 and BGA 120 is illustrated. In various implementations, the RDL may include one or more layers of electrical conductive materials and two or more layers of a dielectric material. The dielectric material may include polyimides, bisbenzocyclotene (BCB), or other materials suitable for forming a redistribution layer on the surface of a semiconductor die.

The method may also include performing a first cut through the semiconductor wafer and the glass lid. The first cut may be performed between each of the plurality of die and cavities. The first cut may extend to the carrier wafer coupled to the second side of the glass lids. FIG. 33 illustrates the structure after the first cut 122 has been performed. The first cut may be performed through sawing. In other implementations, the first cut may be performed through etching.

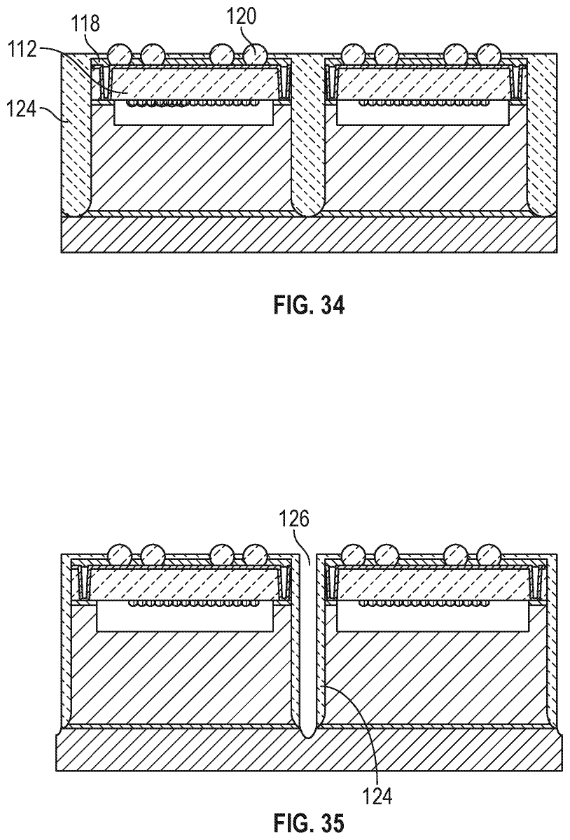

The method further including encapsulating each of the plurality of die with molding compound. The molding compound 124 may extend over the RDL 118, around the edges of the die extending to a second side of the glass lid. The molding compound may also encapsulate a portion of the interconnects on the BGA 120. The structure after encapsulating with molding compound 124 is illustrated in FIG. 34. The method may include performing a second cut. The second cut may extend through the molding compound located between each of the plurality of semiconductor packages. The second cut may be performed using a saw. Referring to FIG. 35, an implementation of two semiconductor packages fully encapsulated and separated by the second cut 126 in the molding compound 124 is illustrated. Each of the plurality of semiconductor packages may be removed from the carrier wafer through a pick and place process.

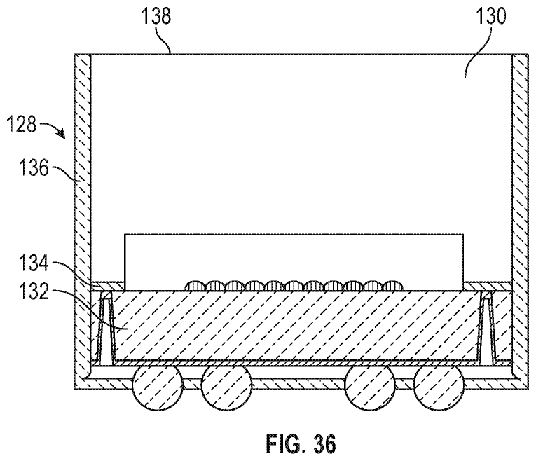

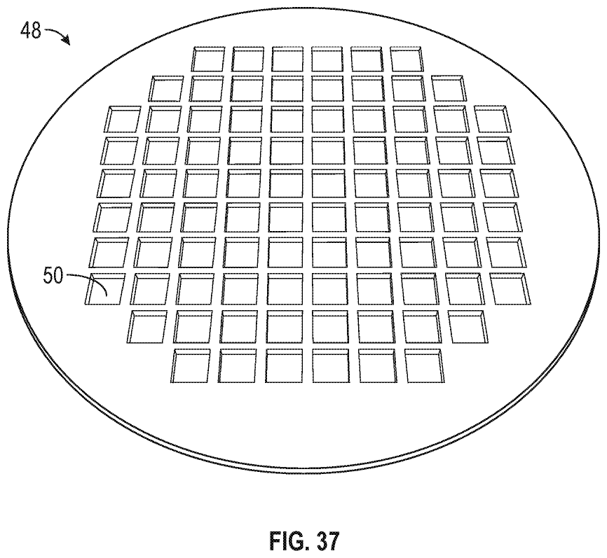

Referring to FIG. 36, an implementation of a semiconductor package after pick and place is illustrated. The package includes a glass lid 130 coupled to an image sensor die 132 through adhesive 134. The adhesive may include, by non-limiting example, epoxy, resin, any adhesives described herein, or any adhesive material used in semiconductor processing. The molding compound 136 is illustrated fully encapsulating the image sensor die 132 and extending to a second side 138 of the glass lid 130. In various implementations, the lid may be formed of another material that is capable of allowing light to reach the active area of the image sensor die. In some implementations, the lid material may be transparent or translucent. In some implementations, the lid material may include plastic.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a die comprising a first side and a second side;
at least two through silicon vias (TSVs) extending from a first side of the die to the second side of the die, the at least two TSVs positioned on opposite sides of an active area of the die;
a glass lid coupled to a second side of the die through adhesive, the adhesive positioned over the at least two TSVs;
a molding compound comprised around a perimeter of the die, extending from the first side of the die to at least the glass lid.

2. The semiconductor package of claim 1, further comprising a redistribution layer (RDL) on a first side of the die.

3. The semiconductor package of claim 1, further comprising a ball grid array coupled to the RDL.

4. The semiconductor package of claim 1, further comprising a die pad between the adhesive and the TSV.

5. The semiconductor package of claim 1, wherein the glass lid comprises a cavity forming a gap between the active area of the die and the glass lid.

6. A method for forming a semiconductor package, the method comprising:
providing a glass cover comprising a plurality of cavities formed therein on a first side of the glass cover;
applying adhesive to the glass cover on a first side and a second side of each of the plurality of cavities;
coupling a plurality of die to each of the plurality of cavities through the adhesive;
applying a molding compound over the plurality of die and to the first side of the glass cover;
after applying the molding compound, forming at least two through silicon vias (TSVs) through each of the plurality of die, the TSVs positioned around an active area of the die;
forming a redistribution layer (RDL) on the first side of each of the plurality of die, the RDL extending over the TSVs; and
singulating each of the plurality of die to form a plurality of semiconductor packages.

7. The method of claim 6, further comprising applying a ball grid array to the RDL over each of the plurality of die.

8. The method of claim 6, wherein forming at least two TSVs through each of the plurality of die and forming a redistribution layer on the first side of each of the plurality of die occurs before applying the molding compound.

9. The method of claim 6, wherein applying the adhesive further comprises applying over a die pad.

10. The method of claim 9, further comprising thinning the molding compound and a first side of each of the plurality of die.

11. The method of claim 6, wherein the each of the plurality of die is an image sensor.

12. The method of claim 6, further comprising filling at least a portion of the TSVs with the adhesive.

13. A method for forming a semiconductor package, the method comprising:
providing a glass cover with a plurality of cavities on a first side of the glass cover;
applying adhesive to the glass cover between each of the plurality of cavities;
coupling a semiconductor wafer to the glass cover over the plurality of cavities, wherein each of a plurality of die correspond with each of the plurality of cavities;
thinning a first side of the semiconductor wafer;
forming at least two through silicon vias (TSVs) through each of the plurality of die, the TSVs positioned around an active area of the die;
forming a redistribution layer (RDL) on the first side of each of the plurality of die, the RDL extending over the TSVs;
performing a first cut between each of the plurality of die;
applying a molding compound over the plurality of die and extending to the first side of the glass cover; and
performing a second cut between each of the plurality of die.

14. The method of claim 13, wherein performing the first cut extends only through the semiconductor wafer.

15. The method of claim 13, wherein performing the first cut extends through the semiconductor wafer and the glass cover between the plurality of die and plurality of cavities, respectively.

16. The method of claim 13, wherein performing the second cut singulates each of the plurality of die to form a plurality of semiconductor packages.

17. The method of claim 13, further comprising applying a ball grid array to a first side of each of the plurality of die.

18. The method of claim 13, further comprising coupling a second side of the glass cover to a carrier wafer.

19. The method of claim 15, further comprising removing each of the plurality of semiconductor wafers from the carrier wafer after performing the second cut.
